(19) United States
(12) Patent Application Publication
(10) Pub. No.: US 2024/0142524 A1
(43) Pub. Date: May 2, 2024

(54) Methods for managing the energy of at least one equipment, corresponding electronic devices and computer program products

(71) Applicant: ORANGE, Issy-les-Moulineaux (FR)

(72) Inventors: Wided Hammedi, CHATILLON CEDEX (FR); David Excoffier, CHATILLON CEDEX (FR); Franck Roudet, CHATILLON CEDEX (FR)

(21) Appl. No.: 18/487,444

(22) Filed: Oct. 16, 2023

(30) Foreign Application Priority Data
Oct. 17, 2022 (FR) 2210706

(51) Int. Cl. G01R 31/367; G01R 31/374; G01R 31/387; G01R 31/56

(52) U.S. Cl. CPC G01R 31/367; G01R 31/374; G01R 31/387; G01R 31/56

(57) ABSTRACT

A method for monitoring the energy of an equipment. The method includes: obtaining a first energy prediction model and an energy measurement frequency; predicting energy, via the prediction model, using, as input for the model, the result of a first energy measurement and contextual data of the equipment during and/or since the first measurement, the prediction being carried out before and/or during a second measurement subsequent to the first measurement and carried out with the obtained measurement frequency with respect to the first measurement; and varying the measurement frequency for a third subsequent energy measurement, as a function of a difference between the predicted energy and the second measurement. A method for building the first energy prediction model, corresponding electronic devices, system, computer program products and recording medium.

### 1. TECHNICAL FIELD

The present application relates to the general field of managing the energy of electronic and/or electromechanical equipment, for example, fixed or mobile equipment belonging to industrial systems or to the Internet of Things, located indoors or outdoors.

Energy “management” is understood herein to mean controlling the energy available to such equipment, as well as the energy contributions and/or consumption of this equipment.

It notably relates to a method for monitoring the energy of at least one electromechanical equipment, and to a method for building a model for predicting the energy of at least one equipment, as well as the electronic devices suitable for implementing such methods, and the corresponding computer program products and recording media.

### 2. PRIOR ART

Energy-consuming equipment is present in many of our environments. Thus, as electromechanical equipment is widely used in industry, communicating objects (also called connected objects) have now flooded all areas of activity, both professional and private.

This equipment can be used to carry out a wide variety of tasks, some more critical than others, and some more energy-intensive than others. Some can operate more or less constantly, while others operate much more irregularly. For example, a communicating object can be used to carry out one-off cryptographic operations or to regularly relay measurements delivered by a sensor.

Furthermore, some of this equipment can benefit from significant energy resources (for example, because it is powered by the mains or by a high-capacity battery), while other equipment has particularly limited energy autonomy. This notably can be the case for equipment that is at least partially powered by one or more renewable energy sources (for example, by photovoltaic energy by being coupled to solar panels). The amount of energy captured by such equipment can vary depending on its environment, and/or depending on when the energy is captured, for example.

As a result of all these factors, the energy consumption of an equipment can sometimes vary greatly over time. Knowing the current energy level of an equipment can be necessary, or at least beneficial, for planning its actions, or providing it with additional energy if necessary (for example, programming a battery recharging action). However, measuring the energy level of an electronic equipment can involve significant energy consumption, even more than the energy consumed by this equipment to carry out some of its tasks.

A non-limiting, exemplary aim of the present application is to propose improvements to at least some of the disadvantages of the prior art.

### 3. SUMMARY

The present application relates to a method for monitoring the energy (for instance the electrical energy) of at least one equipment and/or a method for building a model for predicting such energy.

The present application thus relates to a method for building a model for predicting the current energy of an electromechanical equipment, said method comprising:
building a plurality of prediction models from an initial prediction model, said plurality of prediction models being obtained by a plurality of training phases of said initial prediction model, taking into account a history of measurement results of the current energy of said equipment associated with data representing a context of said equipment between and/or during said measurements, said measurements being carried out with different measurement frequencies or steps in said plurality of training phases;
selecting one of the built models taking into account said measurement frequencies and/or steps, and accuracies of said built models.

“Context” is understood herein to mean, for example, as will be described hereafter, a physical environment of the equipment and/or the activities of this equipment.

In at least some embodiments, the building method comprises transmitting to at least one device data that characterize said selected prediction model, and/or the measurement frequency and/or step used for training said selected prediction model. In at least some embodiments, the building method comprises transmitting to said device at least one indication that relates to at least one type of contextual data used for training said selected prediction model.

The present application also relates to a method for monitoring the current energy of an electromechanical equipment, said method comprising:
obtaining a first model for predicting said current energy of said equipment, and/or a measurement frequency and/or a measurement step of said energy;
predicting, via said prediction model, the energy of said equipment, using, as input for said model, the result of a first measurement of said current energy of said equipment and data representing a context of said equipment during and/or since the first measurement, said prediction being carried out before and/or during a second measurement subsequent to said first measurement and carried out while complying with said obtained measurement frequency and/or measurement step with respect to said first measurement;
varying the measurement frequency and/or step of at least one measurement of the energy of said equipment, subsequent to said second measurement, as a function of a difference between said predicted energy and said second measurement.

In at least some embodiments, the monitoring method comprises obtaining at least one indication relating to at least one type of contextual data to be used for said prediction model, and said obtaining of contextual data takes into account said obtained indication.

In at least some embodiments, obtaining said prediction model, and/or said measurement frequency and/or said measurement step comprises:
building a plurality of prediction models from an initial prediction model, said plurality of prediction models being obtained by a plurality of training phases of said initial prediction model taking into account a history of measurement results of the current energy of said equipment associated with data representing a context of said equipment between said and/or during said measurements, said measurements being carried out with different measurement frequencies or steps in said plurality of training phases;
and said obtained model is selected from said built models taking into account said measurement frequencies and/or steps and accuracies of said built models, said obtained measurement frequency and/or step being the frequency and/or the step of measurements used for training said selected prediction model.

In at least some embodiments of the building method and/or of the monitoring method, the selected model is the prediction model having the lowest measurement frequency and/or the largest measurement step with accuracy above (as an absolute value) a first value (i.e., more accurate than this first value).

In at least some embodiments of the building method and/or of the monitoring method, selecting a model from said built models takes into account an energy capacity of said equipment.

In at least some embodiments, the building method and/or the monitoring method comprises pruning at least one weight of at least one neural network of at least one built prediction model and/or of said selected prediction model.

In at least some embodiments, the building method and/or the monitoring method comprises freezing at least one layer of at least one neural network of at least one built prediction model and/or of said selected prediction model.

In at least some embodiments, said electromechanical equipment can be adapted to be supplied with energy by a module for capturing ambient energy.

“Energy capacity” is understood herein to mean the maximum value of maximum energy that can be measured for the electromechanical equipment.

The present application also relates to a method for building a model for predicting the current energy of an electromechanical equipment comprising:
a plurality of predictions of the evolution of the energy of said electromechanical equipment between at least two instants, with the predicted energy of said electromechanical equipment at a first one of said instants depending on the actual energy of said electromechanical equipment measured at a second one of said instants, preceding said first instant, and on data representing a context (physical environment and/or activity, for example) of said equipment over a time range ranging between said second instant and said first instant;
said first instant being determined by at least taking into account the difference between the predicted energy at said second instant and the actual energy at said second instant.

In at least some embodiments, said electromechanical equipment can be adapted to be supplied with energy by a module for capturing ambient energy.

In at least some embodiments, at least one of said predictions uses, in order to predict the actual energy of said electromechanical equipment at said first instant, a neural network model having as input data the actual energy of said device at said second instant and said contextual data between said first and second instants.

In at least some embodiments, said first instant is determined by also taking into account a ratio between this difference and the energy capacity of said electronic device.

In at least some embodiments, the method comprises receiving a time gap (or measurement step) and/or a measurement frequency to be complied with between two measurements during at least one of said predictions.

The features, which are set forth in isolation in the present application in association with some embodiments of at least one of the methods of the present application, can be combined with one another according to other embodiments of this method. According to another aspect, the present application also relates to an electronic device adapted to implement at least one of the methods of the present application in any one of the embodiments thereof.

For example, the present application thus relates to an electronic device comprising at least one processor configured for:
building a plurality of models for predicting the current energy of an electromechanical equipment from an initial prediction model, said plurality of prediction models being obtained by a plurality of training phases of said initial prediction model taking into account a history of measurement results of the current energy of said equipment associated with data representing a context of said equipment between said and/or during said measurements, said measurements being carried out with different measurement frequencies or steps in said plurality of training phases;
selecting one of the built models taking into account said measurement frequencies and/or steps and accuracies of said built models.

The present application also relates, for example, to an electronic device comprising at least one processor configured for monitoring the current energy of an electromechanical equipment, said monitoring comprising:
obtaining a first model for predicting said current energy of said equipment, and/or a measurement frequency and/or a measurement step of said energy;
predicting, via said prediction model, the energy of said equipment, using, as input for said model, the result of a first measurement of said current energy of said equipment and data representing a context of said equipment during and/or since the first measurement, said prediction being carried out before and/or during a second measurement subsequent to said first measurement and carried out while complying with said obtained measurement frequency and/or measurement step with respect to said first measurement;
varying the measurement frequency and/or step of at least one measurement of the energy of said equipment, subsequent to said second measurement, as a function of a difference between said predicted energy and said second measurement.

The present application also relates, for example, to a system comprising:
at least one electronic device comprising at least one processor configured for:
   building a plurality of models for predicting the current energy of an electromechanical equipment from an initial prediction model, said plurality of prediction models being obtained by a plurality of training phases of said initial prediction model taking into account a history of measurement results of the current energy of said equipment associated with data representing a context of said equipment between said and/or during said measurements, said measurements being carried out with different measurement frequencies or steps in said plurality of training phases;
   selecting one of the built models taking into account said measurement frequencies and/or steps and accuracies of said built models;
at least one electronic device comprising at least one processor configured for monitoring the current energy of said electromechanical equipment, said monitoring comprising:
   obtaining a first model for predicting said current energy of said equipment, and/or said measurement frequency and/or said measurement step of said energy;
   predicting, via said prediction model, the energy of said equipment, using, as input for said model, the result of a first measurement of said current energy of said equipment and data representing a context of said equipment during and/or since the first measurement, said prediction being carried out before and/or during a second measurement subsequent to said first measurement and carried out while complying with said obtained measurement frequency and/or measurement step with respect to said first measurement;
   varying the measurement frequency and/or step of at least one measurement of the energy of said equipment, subsequent to said second measurement, as a function of a difference between said predicted energy and said second measurement.

The present application also relates to a computer program comprising instructions for implementing the various embodiments of at least one of the aforementioned methods, when the computer program is executed by a processor, and a recording medium that can be read by an electronic device on which the computer program is recorded.

For example, the present application thus relates to a computer program comprising instructions for implementing, when the program is executed by a processor of an electronic device, a method comprising:
building a plurality of prediction models from an initial prediction model, said plurality of prediction models being obtained by a plurality of training phases of said initial prediction model taking into account a history of measurement results of the current energy of said equipment associated with data representing a context of said equipment between and/or during said measurements, said measurements being carried out with different measurement frequencies or steps in said plurality of training phases;
selecting one of the built models taking into account said measurement frequencies and/or steps, and accuracies of said built models.

For example, the present application thus relates to a computer program comprising instructions for implementing, when the program is executed by a processor of an electronic device, a method for monitoring the current energy of an electromechanical equipment, said method comprising:
obtaining a first model for predicting said current energy of said equipment, and/or a measurement frequency and/or a measurement step of said energy;
predicting, via said prediction model, the energy of said equipment, using, as input for said model, the result of a first measurement of said current energy of said equipment and data representing a context of said equipment during and/or since the first measurement, said prediction being carried out before and/or during a second measurement subsequent to said first measurement and carried out while complying with said obtained measurement frequency and/or measurement step with respect to said first measurement;
varying the measurement frequency and/or step of at least one measurement of the energy of said equipment, subsequent to said second measurement, as a function of a difference between said predicted energy and said second measurement.

For example, the present application thus relates to a computer program comprising instructions for implementing, when the program is executed by a processor of an electronic device, a method for building a model for predicting the current energy of an electromechanical equipment, the method comprising:
a plurality of predictions of the evolution of the energy of said electromechanical equipment between at least two instants, with the predicted energy of said electromechanical equipment at a first one of said instants depending on the actual energy of said electromechanical equipment measured at a second one of said instants, preceding said first instant, and on data representing a context (physical environment and/or activity, for example) of said equipment over a time range ranging between said second instant and said first instant;
said first instant being determined by at least taking into account the difference between the predicted energy at said second instant and the actual energy at said second instant.

Furthermore, the present application also relates to a recording medium that can be read by a processor of an electronic device and on which a computer program is recorded that comprises instructions for implementing, when the program is executed by the processor, a method comprising:
building a plurality of prediction models from an initial prediction model, said plurality of prediction models being obtained by a plurality of training phases of said initial prediction model taking into account a history of measurement results of the current energy of said equipment associated with data representing a context of said equipment between and/or during said measurements, said measurements being carried out with different measurement frequencies or steps in said plurality of training phases;
selecting one of the built models taking into account said measurement frequencies and/or steps and accuracies of said built models.

Furthermore, the present application also relates to a recording medium that can be read by a processor of an electronic device and on which a computer program is recorded that comprises instructions for implementing, when the program is executed by the processor, a method for monitoring the current energy of an electromechanical equipment, said method comprising:
obtaining a first model for predicting said current energy of said equipment, and/or a measurement frequency and/or a measurement step of said energy;
predicting, via said prediction model, the energy of said equipment, using, as input for said model, the result of a first measurement of said current energy of said equipment and data representing a context of said equipment during and/or since the first measurement, said prediction being carried out before and/or during a second measurement subsequent to said first measurement and carried out while complying with said obtained measurement frequency and/or measurement step with respect to said first measurement;
varying the measurement frequency and/or step of at least one measurement of the energy of said equipment, subsequent to said second measurement, as a function of a difference between said predicted energy and said second measurement.

Furthermore, the present application also relates to a recording medium that can be read by a processor of an electronic device and on which a computer program is recorded that comprises instructions for implementing, when the program is executed by the processor, a method for building a model for predicting the current energy of an electromechanical equipment, the method comprising:
a plurality of predictions of the evolution of the energy of said electromechanical equipment between at least two instants, with the predicted energy of said electromechanical equipment at a first one of said instants depending on the actual energy of said electromechanical equipment measured at a second one of said instants, preceding said first instant, and on data representing a context (physical environment and/or activity, for example) of said equipment over a time range ranging between said second instant and said first instant;
said first instant being determined by at least taking into account the difference between the predicted energy at said second instant and the actual energy at said second instant.

The aforementioned programs can use any programming language, and can be in the form of source code, object code, or of intermediate code between source code and object code, such as in a partially compiled format, or in any other desirable format. The aforementioned information media can be any entity or device capable of storing the program. For example, a medium can comprise a storage means, such as a ROM, for example, a CD-ROM or a microelectronic circuit ROM or even a magnetic recording means.

Such a storage means can be, for example, a hard disk, a flash memory, etc. Moreover, an information medium can be a transmissible medium such as an electrical or optical signal, which can be routed via an electrical or optical cable, via a radio or via other means. A program according to an aspect of the present disclosure particularly can be downloaded over a network of the Internet type.

Alternatively, an information medium can be an integrated circuit, in which a program is incorporated, with the circuit being adapted to execute or to be used to execute any one of the embodiments of at least one of the methods that is the subject matter of the present patent application.

In general, in the present application obtaining an element is understood to mean, for example, receiving this element from a communication network, acquiring this element (via, for example, user interface elements or sensors or other measurement components), creating this element using various processing means such as by copying, encoding, decoding, converting, etc., and/or accessing this element from a local or remote storage medium accessible to at least one device at least partially implementing this obtaining.

### 4. BRIEF DESCRIPTION OF THE DRAWINGS

Further features and advantages of the disclosure will become more clearly apparent upon reading the following description of particular embodiments, which are provided by way of simple illustrative and non-limiting examples, and from the appended drawings, in which:

FIG. 1 shows a simplified view of a system, cited by way of an example, in which at least some embodiments of at least one of the methods of the present application can be implemented;

FIG. 2 shows a simplified view of a device adapted to implement at least some embodiments of at least one of the methods of the present application;

FIG. 3 shows an overview of the building method of the present application, in at least some embodiments thereof;

FIG. 4 illustrates an example of a prediction model according to some embodiments of at least one of the methods of the present application;

FIG. 5 shows an overview of the monitoring method of the present application, in at least some embodiments thereof;

FIG. 6 illustrates another example of a prediction model according to some embodiments of at least one of the methods of the present application;

FIG. 7 illustrates the predicted and measured energy levels according to at least some embodiments of the method of the present application.

### 5. DESCRIPTION OF THE EMBODIMENTS

The aim of the present application is to assist in determining the current energy level of an electromechanical equipment (or object) with an energy level that may fluctuate as a function of its usage context, while limiting the number and/or the frequency of measurements of its actual energy level (for example, the actual charge of one or more batteries powering it), by virtue of a prediction of this energy level.

Notably, the present application can implement, at least in some embodiments, an Artificial Intelligence technique based on a prediction model integrating a functionality for dynamically adapting to the usage context of the equipment. This dynamic adaptation can use, for example, contextual data relating to the equipment, for example, contextual data acquired via data streams, such as streaming.

Unlike some solutions of the prior art, which during an operational phase predict the current energy of an equipment based on measurements solely taken during a prior calibration phase (in a factory, or during a prior initialization or learning phase), the present application proposes taking into account measurements carried out during the operation (or use) of the equipment, so as to measure the relevance of the predictions, and vary the number and/or the frequency of actual measurements as a function of this prediction relevance. Indeed, limiting the number and/or the frequency of measurements of the current energy of at least one battery of an equipment can help to limit the energy consumed by its measurements.

The present application can thus assist in obtaining more reliable predictions than some solutions of the prior art, which assume the energy production and/or consumption profile of a fixed equipment over time: indeed, various factors in practice can cause the energy consumption of an equipment to vary. For example, renewable energy production is inherently variable. Thus, sunshine (or an air or water flow, a temperature difference, vibrations, etc.) can be stronger or weaker depending on the time of day or the weather. As a result, the energy captured in order to power an equipment by this means can vary to a greater or lesser extent throughout the day. Furthermore, the tasks carried out by an equipment (and the energy that they consume) can vary over time.

Finally, the behavior in terms of energy consumption can vary between two equipments for the same model of a manufacturer, or for the same equipment, as it ages or, more specifically, as its electronic components wear.

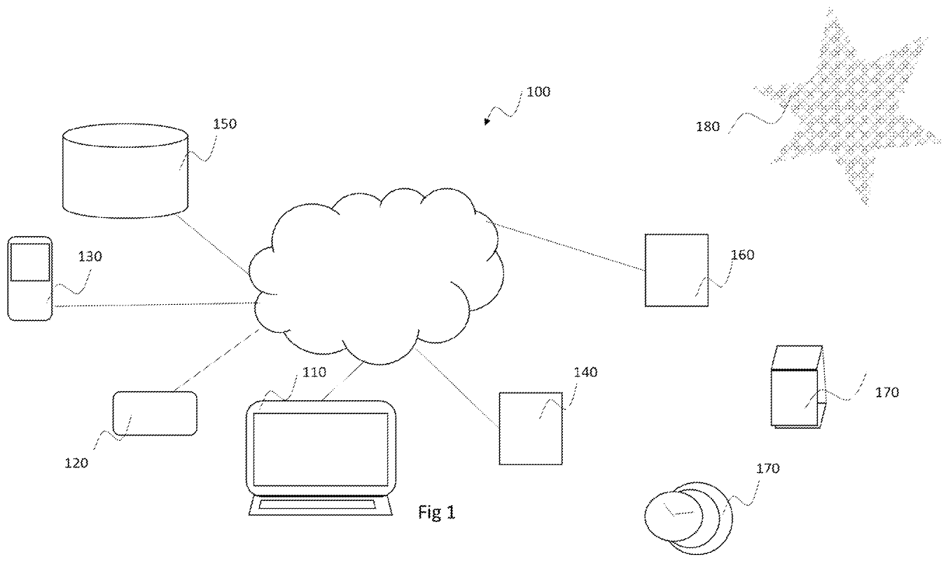

Limiting the measurement of the actual energy of the equipment can also help to increase the lifetime of the one or more measurement components on board the equipment, as these are de facto less stressed than if they were systematically used to determine the battery charge level (or at least help to avoid their premature ageing). The present application will now be described in further detail with reference to FIG. 1. FIG. 1 shows a telecommunications system 100 in which some embodiments of the disclosure can be implemented. The system 100 comprises one or more electronic devices, at least some of which can communicate with each other via one or more communication networks, which are possibly interconnected, such as a Local Area Network (LAN) and/or a Wide Area Network (WAN). For example, the network can include a business or domestic LAN and/or a WAN of the Internet or cellular, GSM (Global System for Mobile Communications), UMTS (Universal Mobile Telecommunications System), Wi-Fi—Wireless, etc. type.

As illustrated in FIG. 1, the system 100 can also include several electronic devices, such as a terminal (such as a laptop 110, a smartphone 130, a tablet 120), connected objects (for example, connected objects 160, 170 equipped with a battery recharged by the mains and/or powered by an ambient energy source 180) or even non-rechargeable, and/or a server 140, for example, an application server, a storage device 150. The system can also include network management and/or interconnection elements (not shown).

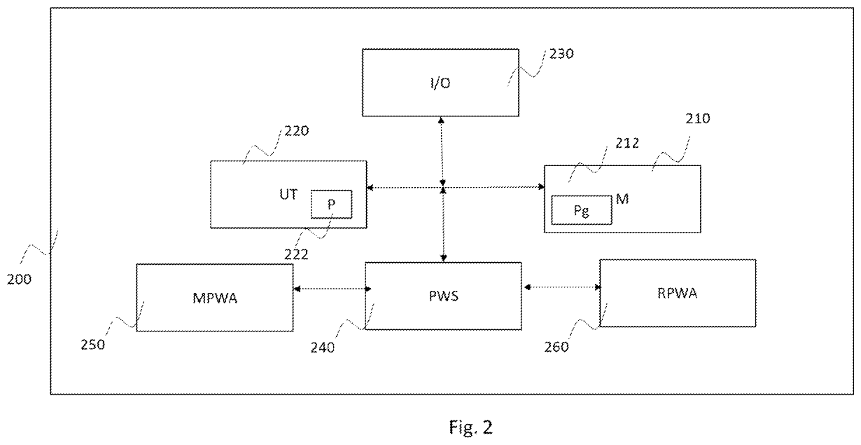

FIG. 2 illustrates a simplified structure of an electronic device 200 of the system 100, for example, one of the devices 110, 120, 130, 140, 150, 160 or 170 of FIG. 1, adapted to implement at least one of the methods of the present application. As illustrated, according to the embodiments, this can be a server, a terminal or a connected object.

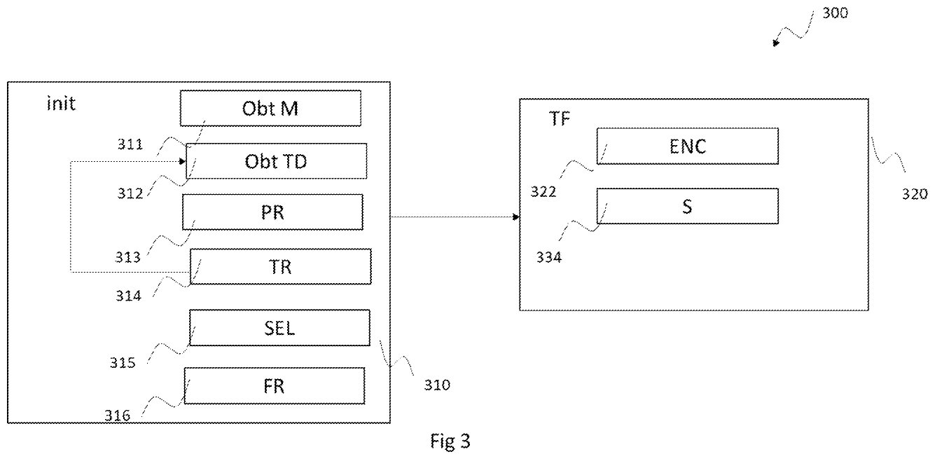

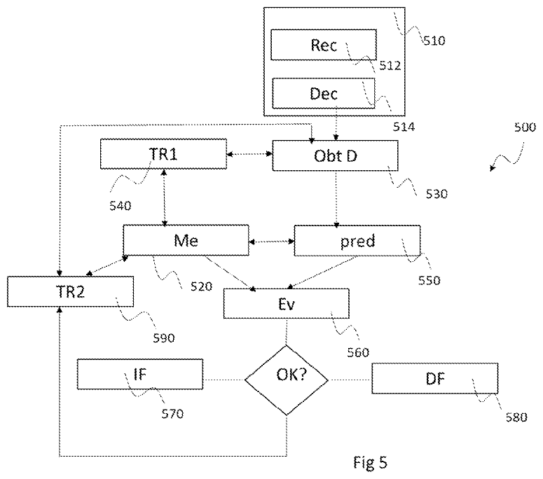

Notably, the device 200 comprises at least one memory M 210. The device 200 can notably comprise a buffer memory, a volatile memory, for example, of the RAM (Random Access Memory) type, and/or a non-volatile memory (for example, of the ROM (Read Only Memory) type). The device 200 can also include a processing unit UT 220, equipped, for example, with at least one processor P 222, and controlled by a computer program PG 212 stored in the memory M 210. Upon initialization, the code instructions of the computer program PG are loaded, for example, into a RAM memory before being executed by the processor P. Said at least one processor P 222 of the processing unit UT 220 can notably implement, individually or collectively, any one of the embodiments of one and/or other of the methods of the present application (notably described with reference to FIGS. 3 and 5), according to the instructions of the computer program PG.

The device 200 can include, for example, (or be coupled to) an energy storage module PWS 240 (such as a battery), an energy supply module MPWA 250, coupled, for example, via a connection module, to the mains, and/or an ambient energy acquisition module RPWA 260 (via solar cells, for example, or any other ambient energy supply mode).

The device can also comprise, or be coupled to, at least one input/output (I/O) module 230, such as a communication module, allowing, for example, the device 200 to communicate with other devices in the system 100, via wired or wireless communication interfaces, and/or such as a module for interfacing with a user of the device (also more simply called “user interface” in this application).

The user interface of the device is understood to mean, for example, an interface integrated into the device 200, or part of a third-party device coupled to this device by wired or wireless communication means. For example, it can be a secondary screen of the device or a set of loudspeakers connected to the device by wireless technology.

A user interface notably can be a user interface, called “output” user interface, adapted to render (or to control rendering of) an output element of a computer application used by the device 200, for example, an application at least partially running on the device 200 or an “online” application at least partially running remotely, for example, on the server 140 of the system 100. Examples of an output user interface of the device include one or more screens, notably at least one graphic screen (touch screen, for example), one or more loudspeakers, a connected headset.

In addition, a user interface can be a user interface, called “input” user interface, adapted to acquire a command from a user of the device 200. It notably can be an action to be carried out in association with a rendered item, and/or a command to be transmitted to a computer application used by the device 200, for example, an application at least partially running on the device 200 or an “online” application at least partially running remotely, for example, on the server 140 of the system 100. Examples of an input user interface of the device 200 include an audio and/or video acquisition means (microphone, camera (webcam), for example), a keyboard, a mouse.

Such input/output means can be adapted, for example, to the parameterization of the device 200.

In some embodiments, the input/output modules can also include means for obtaining energy measurements. According to the embodiments, this can involve communication means adapted to receive the results of measurements carried out by another device on equipment whose energy level is to be monitored, and/or means for carrying out these measurements on said device (so as to measure its own energy).

The energy of the equipment and/or of the device can be measured, for example, via one or more specific electronic components incorporated in the equipment and/or the device itself, each directly measuring the energy level on the terminals of a battery of the equipment and/or of the device. An example of such a component is the component referenced INA 231 by Texas Instruments©.

In some embodiments, the input/output modules can also include means for obtaining contextual data, representing, for example, the ambient context (or physical environment) of an equipment, or the activity of the device during and/or between energy measurements. According to the embodiments, this can involve communication means adapted to receive such data acquired on at least one other device (such as a sensor for brightness, temperature, humidity, pressure, etc.), located, for example, in the vicinity of an equipment whose energy level is to be monitored, and/or means for acquiring such data. These acquisition means can include physical or software sensors (for example, software probes adapted to measure a number and/or a frequency of demands made on the equipment by a user, and/or a number and/or a frequency (and possibly a type) of data (such as messages) sent and/or received by the equipment). Said at least one microprocessor of the device 200 notably can be adapted for:
building a plurality of models for predicting the current energy of an electromechanical equipment from an initial prediction model, said plurality of prediction models being obtained by a plurality of training phases of said initial prediction model taking into account a history of measurement results of the current energy of said equipment associated with data representing a context of said equipment between said and/or during said measurements, said measurements being carried out with different measurement frequencies or steps in said plurality of training phases;
selecting one of the built models taking into account said measurement frequencies and/or steps and accuracies of said built models.

Said at least one microprocessor of the device 200 notably can be adapted for monitoring the current energy of an electromechanical equipment, the monitoring comprising:
obtaining a first model for predicting said current energy of said equipment, and/or a measurement frequency and/or a measurement step of said energy;
predicting, via said prediction model, the energy of said equipment, using, as input for said model, the result of a first measurement of said current energy of said equipment and data representing a context of said equipment during and/or since the first measurement, said prediction being carried out before and/or during a second measurement subsequent to said first measurement and carried out while complying with said obtained measurement frequency and/or measurement step with respect to said first measurement;
varying the measurement frequency and/or step of at least one measurement of the energy of said equipment, subsequent to said second measurement, as a function of a difference between said predicted energy and said second measurement.

Said at least one microprocessor of the device 200 notably can be adapted for:
a plurality of predictions of the evolution of the energy of said electromechanical equipment between at least two instants, with the predicted energy of said electromechanical equipment at a first one of said instants depending on the actual energy of said electromechanical equipment measured at a second one of said instants, preceding said first instant, and on data representing a context (physical environment and/or activity, for example) of said equipment over a time range ranging between said second instant and said first instant;
said first instant being determined by at least taking into account the difference between the predicted energy at said second instant and the actual energy at said second instant.

In some embodiments, the above methods can be implemented in a distributed manner between at least two devices 110, 120, 130, 140, 150, 160 and/or 170 of the system 100. Thus, the present application is sometimes described with reference to a first device (for example, a server 140 of the system 100) building a model (according to the above building method) that it communicates to at least one second device (for example, a terminal 110 or a storage device 150 of the system 100, from which the terminal 110 can subsequently obtain this model). A second device (for example, the terminal 110) can use this model (according to the above monitoring method) to monitor the energy of a third device (such as a connected object 160 or 170).

In other embodiments, the monitoring method of the present application can be implemented locally by equipment receiving a model from another device (for example, a server 140 or the storage device 150) and using it to monitor its own energy. In yet further embodiments, the monitoring method of the present application can be implemented locally by an equipment building its own model and monitoring its own energy.

Some of the above input-output modules are optional and therefore can be absent from the device 200 in some embodiments. Notably, when the methods are locally implemented by an equipment building its own model and monitoring its own energy, some input/output modules linked to the transmission or reception of data can be absent.

The term “module” or the term “component” or “element” of the device is understood herein to mean a hardware element, notably a wired element, or a software element, or a combination of at least one hardware element and of at least one software element.

The methods according to one or more aspects of the present disclosure therefore can be implemented in various ways, according to their embodiments, notably in wired form and/or in software form.

Some embodiments of the present application will now be described, with reference to FIGS. 3 to 5, in which a building method 300, illustrated in FIG. 3, is implemented on a first electronic device (which can be similar to the device 200 of FIG. 2), such as the server 140 illustrated in FIG. 1 and a monitoring method 500 is implemented on a second electronic device (which can be similar to the device 200 of FIG. 2), such as the terminal 110 of FIG. 1. For the sake of clarification, the following will be used throughout the remainder of the present application:

the term “first device” will be used to refer to the device implementing the building method of the present application;

the term “second device” will be used to refer to the device implementing the monitoring method of the present application, i.e., the monitoring device; and

the term “equipment”, or “electromechanical equipment”, or “connected object”, will be used to refer to the device whose energy is monitored, i.e., the monitored device.

As explained above, according to the embodiments this can involve the same device or different devices.

Building the prediction model on a “first” device other than the device monitoring the equipment or the monitored equipment itself can, during this building step, help to take advantage of computing and/or processing resources of the first device that are greater than those available on the device monitoring the equipment or on the equipment itself. Similarly, monitoring the energy of the equipment via a “second” device can, during this monitoring step, help to take advantage of computing and/or processing resources of the second device that are greater than those available on the equipment itself.

In addition, implementing building of the prediction model and/or the monitoring of energy on devices other than the equipment itself can allow models to be built and/or monitoring to be carried out for several items of equipment within the same device and therefore enable some processing operations to be pooled.

Furthermore, local implementation on the equipment or on the second device can help to simplify the implementation of the solution that is the subject matter of this application, and therefore help to limit its implementation cost. In particular, some steps of the methods described hereafter (for example, transmission of the selected model and/or the associated frequency) can be optional in such embodiments.

FIG. 3 illustrates the method 300 for building a prediction model of the present application, in an implementation on a first device (such as a server).

As illustrated, the method 300 can include a model obtaining phase 310, during which phase a prediction model is initialized that then can be used to predict the energy of the equipment by the second device (or by the equipment itself).

More specifically, during the obtaining 310, a model for predicting a current energy (or charge) of the equipment is defined and then trained via machine learning. Obtaining thus includes, defining 311 an initial model.

More specifically, during the obtaining 310, a model for predicting a current energy (or charge) of the equipment is trained via machine learning. Obtaining thus includes, in the illustrated embodiment, defining 311 an initial model which is then trained. The charge of the equipment at a current instant (t1) is linked to its charge at an instant (t0), preceding this current instant, and to the evolution of the environment of the equipment between the instants t0 and t1. Therefore, as in the example shown in FIG. 3, the prediction model can assume, as input parameters, an energy value that is measured prior to the current instant (i.e., the actual energy measured at an instant t0 preceding the current instant t1) (for example, the result of at least one of the last n energy measurements taken (where n is an integer), such as the last or the last n measurements carried out) and at least one contextual datum relating to the context of the equipment over the time interval that has elapsed since this measurement or these measurements (i.e., the time interval between t0 and t1). The at least one contextual datum can include, for example, at least one datum relating to the ambient environment of the equipment, such as a current value and/or a variation in ambient brightness, ambient temperature, pressure and/or ambient humidity within this time interval. The at least one contextual datum can include, for example, at least one datum relating to external energy received by the equipment (via the mains, for example). The at least one contextual datum can also include, for example, at least one datum relating to the activity of the equipment, such as the nature of at least one completed task representing energy consumption, the number of times the task is repeated, the duration of the task, the number and/or frequency of requests made by a user, the number and/or frequency of data (for example, messages) sent and/or received by the equipment, the type and/or the size of data sent, received or, more generally, processed by the equipment, etc.

In the example shown, where the equipment to be monitored is at least partially powered by an ambient energy source, the initial model can be, for example, a multi-input non-linear regression model. Indeed, in machine learning, regression covers the statistical analysis methods for predicting a quantitative variable on the basis of other variables that are correlated therewith. Since the energy variation (i.e., its energy charge and/or discharge) of the equipment to be monitored is unknown, and since the energy variation can be affected by external factors that vary over time (as explained above), which can give it a non-linear character, the initial model can be selected as a non-linear regression model.

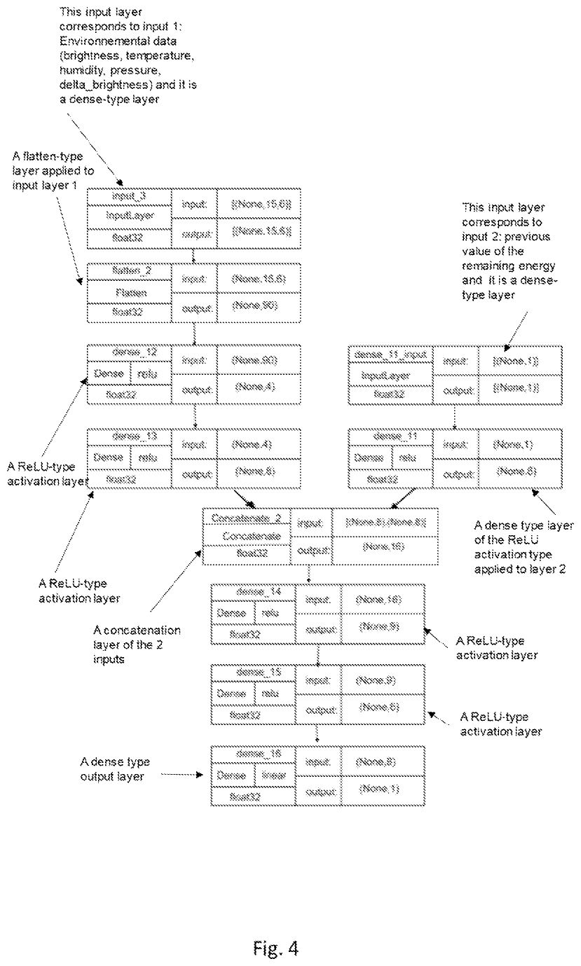

In some embodiments where defining (or obtaining) 311 the model uses neural network technology, defining 311 can include selecting and/or adjusting the hyperparameters (number, type and size of the layers, overall size, etc.) of the model being defined via a software tool for adjusting hyperparameters of artificial intelligence models, such as the Keras Tuner© tool, for example. Thus, FIG. 4 illustrates an example of a prediction model obtained using the Keras Tuner© hyperparameter adjustment tool. In particular, as in this example, the tool that is used can be provided with minimum and maximum limits for the hyperparameters, so as to help to obtain a model that is adapted (in terms of size and/or processing time) to a device on which an inference of the model is expected (such as the “second” device and/or the equipment to be monitored (such as the connected objects 160, 170)).

Furthermore, as illustrated in the example in FIG. 3, the method can include a phase of obtaining 312 training (or learning) data. In some embodiments, this can be data relating to the equipment to be monitored. For example, it can involve receiving or acquiring a plurality of energy values measured on this equipment at several instants, and contextual data (environmental and/or activity data) relating to the time intervals between these instants.

As a variant, in some embodiments, the learning data can be data relating to equipment other than the equipment to be monitored that is the same model as the equipment to be monitored, or data obtained, during a test phase, for example, on completion of manufacturing of the equipment to be monitored.

In the illustrated embodiment, the building method 300 can include a learning phase 314 (also called training) implemented from the previously built initial model 311 to adjust the parameters (weight, bias, etc.) of the layers of this model on the basis of the obtained training data 312.

The learning phase 314 can be repeated, for example, until at least one stop criterion is reached. For example, a stop criterion can be reaching or exceeding a required accuracy level for the model.

In the present application, the “accuracy” of the model refers to the absolute value of the difference between the energy predicted by the model and the actual (measured) energy.

The required accuracy of the model (denoted “Diff-req” hereafter) refers to a maximum value of the accuracy.

In this way, the aforementioned stop criterion can reflect accuracy (and therefore the absolute value of the difference) below (in absolute terms) a certain value corresponding to the required accuracy of the model.

This required accuracy can be parameterized, for example, and can differ depending on the nature of the equipment being monitored.

Other criteria can be taken into account in other embodiments. For example, a stop criterion can be an “excessively low” variation in this difference, even if it remains greater than the required accuracy (for example, a variation in the difference that remains below a certain parameterizable constant value for a parameterizable number of successive iterations). Stated simply, a stop criterion would be the “stagnation” of the accuracy obtained on completion of learning at a value that remains higher than the required accuracy (therefore, a value that is “worse” than the required accuracy).

As illustrated in FIG. 3, in some embodiments, the training phase 314 can be carried out several times, with different measurement time gaps. For example, each learning phase can use historical data corresponding to a constant time gap (or “step”) between measurements, with this gap being different from one learning phase to the next (for example, each gap of the learning phases is different from the others). For example, an increasingly large measurement step (i.e. decreasing frequencies) can be used for successive different training phases, increased, for example, upon each iteration by a multiplicative coefficient, or by adding a certain constant to the measurement step (or subtracting it from the frequency). The variation in the measurement frequency and/or step can notably depend on the equipment to be monitored. For example, minimum and maximum values can be selected as a function of the equipment to be monitored, and its maximum energy resources, its average consumption over a reference period, etc. Thus, this results in a plurality of trained models with different measurement steps (or different frequencies) based on the initial model. Such embodiments can include selecting 315 at least one of the trained models as a function of the measurement steps used during the various learning phases and the accuracy of at least one of these models. Such embodiments can help to limit the number and/or the frequency of the measurements, while helping to comply with the required accuracy. This involves, for example, selecting the lowest measurement frequency that allows the required accuracy Diff-req to be achieved. The frequency selected during this obtaining phase 310 will be denoted (F1) throughout the remainder of the application.

In the embodiment illustrated in FIG. 3, the building method 300 can include at least one (optional) optimization of the model. This optimization can be carried out, according to the embodiments, before or after learning and, in this case, on all the trained models or only on the one or more selected trained models. Optimizing the model before training can help to limit the resources (in terms of time and computing capacity) required for the various training phases. For example, in some embodiments, a first optimization 313 can implement, for example, pruning techniques, i.e., optimization techniques that (for example, progressively) set the least significant weights of the model to zero so as to reduce the weight matrices of the model (and therefore its memory footprint and the resources required for its use during learning as in a subsequent inference). Such an embodiment therefore contributes to the parsimony of the model. According to the embodiments, for example according to the memory and processing capacities of the device 200, various pruning techniques can be used. For example, in some embodiments, pruning can use a technique that is identical or similar to that described by T. Yang, Y. Chen and V. Sze (“Designing Energy-Efficient Convolutional Neural Networks Using Energy-Aware Pruning”, 2017 IEEE Conference on Computer Vision and Pattern Recognition (CVPR), 2017, pp. 6071-6079, doi: 10.1109/CVPR.2017.643).

Optimization 313 by pruning the model can help to limit the size and the complexity of the model so as to make it suitable for the memory and processing capacities of a second device and/or an equipment on which it is to be used (see, for example, the monitoring method described hereafter), and notably of a second device and/or an equipment with lower memory and processing capacities than those of the first device. In the example shown in FIG. 3, the method can comprise a second optimization 316 (also optional) of the models (for example, of all the models once trained or only of the one or more selected models).

This second optimization 316 can include, for example, “freezing” at least one layer of the model (for example, one of the upper layers), while leaving at least one other layer (for example, one of the last layers) unfrozen. Freezing (or setting) layers in this case means deactivating the computation of the gradient and the backpropagation of the weights of these layers (which are therefore “frozen”, i.e., no longer evolve). The first layers of a neural network (for example, that or those receiving the input data of the model) encode the general features of the input data. Thus, for example, the first layers of the built model find general links between the charging and/or discharging curve of the equipment and the environmental data. The final layers are more specific to an activity (or task), specific to the equipment, or to particular environmental conditions. For example, the general features can be expressed by a positive correlation between the energy and the environment (the fact that the energy decreases when the brightness decreases) and the details can be expressed by exact data values (for example, the model can learn from its lower layers that when the brightness increases by x lux, the energy will increase by y V).

Freezing at least one upper layer can help reduce the risks of overadjusting (or overlearning) of the prediction model. Overlearning can occur when the model becomes highly (or even excessively) linked to the learning data. Freezing the upper layers, for example, can help the model to retain its general knowledge (obtained during the learning phase).

Freezing at least one upper layer can also help to limit the memory and processing resources required for optional retraining of the model (since only the unfrozen layers will be retrained).

In some embodiments, where the equipment is monitored by another device (the second device or the equipment itself), the method can include transferring 320 to this other device the selected model and/or the measurement frequency and/or step used for the training thereof. Optionally, other parameters can be transferred, such as indicators representing the type of contextual data used when training the model. This transferring can involve, for example, sending 324 parameters (hyperparameters, weights, bias) characterizing the model.

In some embodiments, transferring 520 can comprise encoding 322 (such as compressing) at least some of the elements to be sent, such as the model parameters. Some embodiments of the monitoring method 500 of the present application will now be described with reference to FIG. 5. The method 500 can be implemented, for example, by a “second” electronic device monitoring an electromechanical equipment or within this equipment itself.

As described hereafter with reference to FIG. 5, the monitoring method 500 can include obtaining 510 a prediction model and/or data associated with this model. More specifically, in some embodiments this can involve receiving 512 a model and associated data comprising, for example, a measurement frequency (F1) and/or step and/or indications relating to the types of contextual data considered when building the model. This model can be, for example, a model that has already been trained and possibly optimized (built, for example, using the method 300 described above with reference to FIGS. 3 and 4). In some embodiments, the method can include, as illustrated, optional decoding 514 of received elements (resulting from a prior compression) in order to obtain this model and its associated data.

As a variant, obtaining 510 the prediction model and its associated data can include building (not illustrated) the prediction model, in a manner similar to that described above in conjunction with obtaining the prediction model (and its associated data) according to the building method 300.

In some embodiments, the method 500 includes, on the one hand, obtaining 520 a plurality of results of measurements of the energy of the equipment to be monitored. These measurements can be carried out with a frequency (F1) corresponding to the measurement frequency and/or step obtained in association with the prediction model. The method 500 can also include, at the same time as the measurements, obtaining 530 data relating to the context (environment, activity, etc.) of the equipment during and/or between these measurements.

In some embodiments, for example, when the model has been learnt on another device (as illustrated in FIG. 3, for example), the method 500 can include learning 540 the obtained prediction model 510 on data specific to the equipment to be monitored and corresponding to its immediate context (in terms of environment and/or activity). This learning phase 540 can be based, for example, on a history of measurements of the energy of the equipment (for example, a history of around ten measurements), as well as on contextual data (environmental and/or relating to its activity, for example) during and/or between these measurements. In some embodiments, such learning can be carried out before any inference of the model.

Indeed, the obtained model 510 may have been previously trained on another type of equipment or with contextual data (environmental conditions, equipment activity) that is quite different from the current conditions of the equipment.

This new learning can help, for example, the prediction model to be subsequently aligned more quickly, during its inference, with the actual behavior of this equipment in terms of energy, in its current context, due to the similarity between the training data (relevant equipment, environmental and activity context, etc.) and the data used as input for the model during its inference to predict the energy of this equipment. According to FIG. 5, the method 500 comprises an inference (or deployment) of the prediction model, so as to be able to estimate the current energy of the equipment between two measurements of its actual energy.

Such estimates can be used, for example, to predict risks of discharging the equipment to be monitored and/or adopt preventive actions as a result, such as modifications to at least one activity of the equipment to be monitored (such as limiting or prohibiting some energy-consuming actions), or adding or activating an ambient energy source (switching on a lamp in the vicinity of the equipment to be monitored), or connecting the equipment to an energy source such as the mains or a secondary battery.

For example, in some embodiments, a prediction 550 can be carried out periodically or following the obtaining of at least one item of contextual data, so as to take into account, for example, the impact of changes in contextual data (change in the features of the environment and/or change in the activity of the equipment) on the energy level of the equipment.

For example, this can involve contextual data (for example, environmental data) periodically gathered with a higher frequency than the frequency of the energy measurements (for example, a frequency several times (for example, 3 to 6 times) greater than the frequency of the energy measurements) or with a period shorter than the energy measurement steps. It can also involve non-periodically (or even randomly) obtained contextual data, such as contextual data linked to the occurrence of an event (for example, equipment activity) to which it relates.

This contextual data can be extracted, for example, from data streams received by the second device from the equipment, or from third-party devices (sensors, for example) located in the vicinity of the equipment.

Notably, the prediction 560 can be made when the (current) result of an energy measurement of the equipment is obtained, so as to be able to check the accuracy of the prediction model.

Thus, in some embodiments, the method can include comparing the measured value of the energy at a current instant t with a predicted value of the energy of the equipment, at the same current instant t, derived from the prediction model obtained (and possibly trained locally). The result of this comparison corresponds to the current accuracy of the prediction model. In some embodiments, the method 500 can include a variation 570, 580 of the measurement frequency (or of the measurement step) at least as a function of the current accuracy of the model. This variation can be implemented, for example, when the accuracy of the model remains greater than the required accuracy Diff-Req for several successive measurements, and corresponds to a reduction 580 in the frequency of measurements (or an increase in the measurement step). Indeed, frequently measuring energy is pointless if the model can predict it with the required accuracy. Furthermore, spacing apart the measurements allows the energy consumed by these measurements to be limited.

Conversely, this variation can be implemented, for example, when the accuracy of the model remains below the required accuracy Diff-Req for several successive measurements, and corresponds to an increase 570 in the frequency of measurements (or a decrease in the measurement steps).

The variation in the measurement frequency and/or step can differ according to the embodiments. For example, a multiplication factor strictly greater than 1 can be applied to the current frequency in order to increase the frequency of measurements, and a multiplication factor strictly less than 1 can be applied to the current frequency in order to reduce the frequency of measurements (or vice versa for a measurement step).

In some embodiments, the method can include, during model inference, retraining 590 the prediction model when its accuracy becomes too low, i.e., when the absolute value of the difference between measured and predicted energies becomes greater than a value (denoted MaxDiff herein) (and used, for example, as a threshold) during one or more consecutive measurements. This value MaxDiff can depend on the nature of the equipment and/or the required accuracy Diff-Req introduced above.

A significant difference can correspond to a sudden change in the environment (a lamp coming on, for example, for an equipment located inside a building, or a cloud suddenly lowering the brightness for an equipment located outside). The difference can also correspond to a sudden introduction of external energy to the equipment (the equipment is connected to an external power source), or even to a sudden change in the activity of the equipment (for example, the beginning or the end of the activity of the equipment).

Retraining the prediction model, even with a small amount of learning data, can help the prediction model to adapt more quickly to such sudden changes. For example, the retraining can be carried out with a smaller amount of data than when training locally prior to the start of the inference of the model.

In at least some embodiments, the methods of the present application can thus help to extend the lifetime of an equipment (or at least help to limit any ageing of the equipment caused by measurements of its energy) by limiting the number of energy measurements carried out on the equipment.

Taking into account contextual data (relating to the physical environment of the equipment and/or its activity) in the prediction, such as the charge of the equipment as previously measured, can also help to obtain better accuracy of the prediction model, which can allow more appropriate or earlier actions to be implemented than with conventional energy measurement methods. Such actions can help, for example, to avoid equipment power failures, and/or help to keep the equipment active for longer, and/or help to better manage the production and/or consumption capabilities of the equipment.

The present application has been described, for the sake of simplification, with the required accuracy of the prediction model being identical during the training and inference phases. In some embodiments, different accuracies can be required for the prediction model during the training and inference phases.

In particular, during the inference phase, the required accuracy of the prediction model at a current instant can vary in some embodiments as a function of the predicted and/or measured value of the equipment at an instant preceding the current instant. Such an embodiment can allow, for example, the frequency of the measurements to be further limited when the actual energy of the equipment decreases, or even allow them to be eliminated, when the current energy of the equipment becomes very low (so as to prevent, for example, the last energy resources of the equipment being wasted on measuring this energy).

The present application can be applied to any type of fixed or mobile “IoT” (Internet of Things) or industrial equipment requiring, for example, accurate management of its energy consumption and/or production for the operation thereof, or requiring accurate short-term prediction (such as in the next few minutes) of its own consumption and/or production.

The results of implementing some embodiments of the present application in order to determine (by estimating and/or measuring) the current energy of a test equipment of the applicant (Orange Computing Cube) will now be described. This equipment is a connected object drawing its operating energy solely from solar energy.

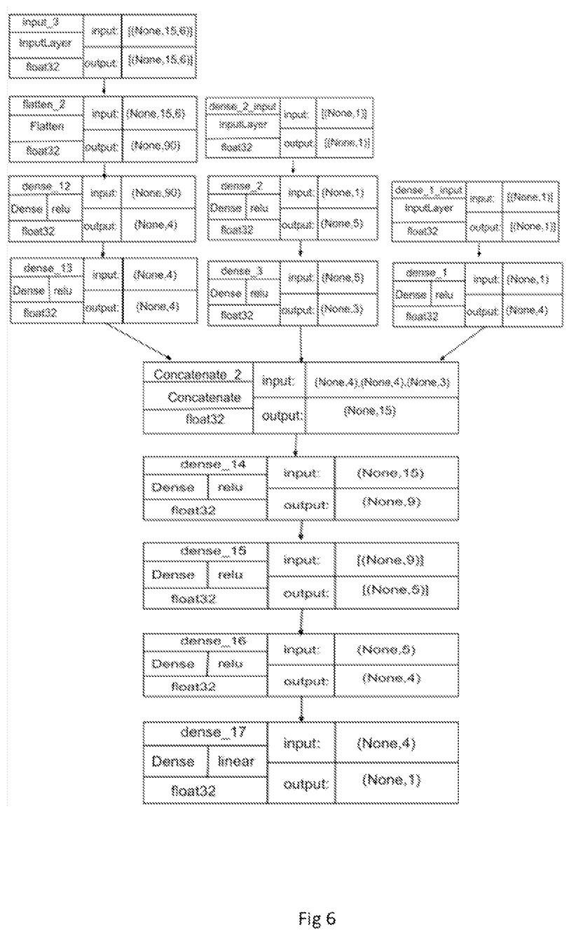

The prediction model is built on a third-party device. The built prediction model is the model illustrated in FIG. 4, as already introduced, where the contextual input data solely represents the environment of the equipment, or, as a variant, the model shown in FIG. 6, where the contextual input data represent both the environment of the equipment and its activity.

In this implementation, the size of the model built according to FIG. 4 is 5 kilobytes and then, after pruning, it is 3.6 kilobytes, while the size of the model built according to FIG. 6 is 7 kilobytes and then, after pruning, it is 6.1 kilobytes.

The model selected on the basis of the model of FIG. 4 is a trained model with a measurement frequency of 30 minutes. The measurement frequency for contextual data is 2 minutes.

The last 2 layers of the model are frozen before the model is transferred to the test equipment.

Local training of the model is carried out following the transfer, using the last 6 completed energy measurements, and the corresponding gathered contextual data. It also can be carried out again, if the difference between the predicted energy and the measured energy is greater than 1% of the maximum charge of the equipment (in this case 0.4 Joule). In this case, the retraining uses the last 2 completed energy measurements, and the corresponding gathered contextual data.

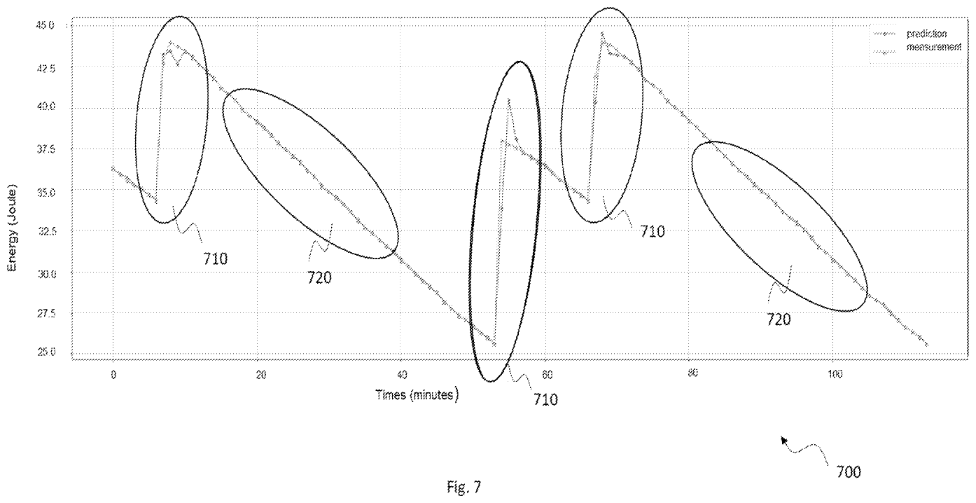

FIG. 7 shows the test results obtained for an Orange Computing Cube. The zones surrounded by circles 710 show a sudden increase in energy due to a sudden change in the environment. The initial model is unable to follow these sudden changes immediately, so the model is retrained on the object. In this case, the retraining can be carried out using a small amount of measured data (energy measured by the INA+environmental data from the various sensors on-board the object or from third-party sensors) (for example, 2 items of data for the model linked to the Computing Cube).

The object can also dynamically reduce the frequency of sensor measurements if it determines that the model is accurate for the last n points. This behavior is illustrated by the zone surrounded by a circle 720.

It should be noted that the model is very well aligned with the measured values (the predicted and actual values are almost equal). Thus, there is no need to actually measure all the subsequent values if the model can predict them accurately. The object can thus optimize its energy consumption.

The following Algorithm 1 can be used, for example: algorithm for dynamically reducing measurement frequency.
Input: E_measured, E_predicted, F1
Output: F2
1. Measure the current energy value (E_measured) for each F1
2. Predict the current energy value using the model (E_predicted) for each F1
3. Compute the difference (e) between the 2 values=|E_measured−E_predicted|
4. If e<threshold for n consecutive times,
then the object assumes that E_predicted=E_measured and skips x measurements=>new measurement frequency of the INA (F2)=(x+1)*F1 (for example, x=1 if the object decides to skip a single measurement).

A non-limiting exemplary aspect of the present application can thus help to extend the lifetime of objects by adapting their operating mode to the energy available in the ambient environment and to the energy stored in their battery. As a result, the objects can, for example, run out of energy less often and/or remain active for longer.

Although the present disclosure has been described with reference to one or more examples, workers skilled in the art will recognize that changes may be made in form and detail without departing from the scope of the disclosure and/or the appended claims.

What is claimed is:

1. A method implemented by an electronic device and comprising:
building a plurality of prediction models from an initial prediction model, said plurality of prediction models being obtained by a plurality of training phases of said initial prediction model taking into account a history of measurement results of a current energy of an electromechanical equipment associated with data representing a context of said equipment between and/or during said measurements, said measurements being carried out with different measurement frequencies in said plurality of training phases;
selecting one of the built models taking into account said measurement frequencies and accuracies of said built models.

2. The method according to claim 1, comprising transmitting to at least one device data that characterize said selected prediction model, and/or the measurement frequency used for training said selected prediction model.

3. The method according to claim 1, comprising transmitting to said device at least one indication that relates to at least one type of contextual data used for training said selected prediction model.

4. The method according to claim 1, wherein the selected model is the prediction model having a lowest measurement frequency with accuracy above a first value.

5. The method according to claim 1, wherein selecting a model from said built models takes into account an energy capacity of said equipment.

6. The method according to claim 1, comprising pruning at least one weight of at least one neural network of at least one built prediction model and/or of said selected prediction model.

7. The method according to claim 1, comprising freezing at least one layer of at least one neural network of at least one built prediction model and/or of said selected prediction model.

8. A method implemented by an electronic device and comprising:
obtaining a first model for predicting said current energy of said equipment, and a measurement frequency of said energy;
predicting, via said prediction model, the energy of said equipment, using, as input for said model, a result of a first measurement of said current energy of an electromechanical equipment and data representing a context of said equipment during and/or since the first measurement, said prediction being carried out before and/or during a second measurement subsequent to said first measurement and carried out while complying with said obtained measurement frequency with respect to said first measurement; and
varying the measurement frequency of at least one measurement of the energy of said equipment, subsequent to said second measurement, as a function of a difference between said predicted energy and said second measurement.

9. The method according to claim 8, wherein the method comprises obtaining at least one indication relating to at least one type of contextual data to be used for said prediction model, and wherein said obtaining of contextual data takes into account said obtained indication.

10. The method according to claim 8, wherein obtaining said prediction model and said measurement frequency comprises:
building a plurality of prediction models from an initial prediction model, said plurality of prediction models being obtained by a plurality of training phases of said initial prediction model taking into account a history of measurement results of the current energy of said equipment associated with data representing a context of said equipment between said and/or during said measurements, said measurements being carried out with different measurement frequencies in said plurality of training phases;
and wherein said obtained model is selected from said built models taking into account said measurement frequencies and accuracies of said built models, said obtained measurement frequency being the measurement frequency used for training said selected prediction model.

11. The method according to claim 8, wherein the selected model is the prediction model having a lowest measurement frequency with accuracy above a first value.

12. The method according to claim 8, wherein selecting a model from said built models takes into account an energy capacity of said equipment.

13. The method according to claim 8, comprising pruning at least one weight of at least one neural network of at least one built prediction model and/or of said selected prediction model.

14. The method according to claim 8, comprising freezing at least one layer of at least one neural network of at least one built prediction model and/or of said selected prediction model.

15. An electronic device comprising at least one processor configured to implement the method of claim 1.

16. An electronic device comprising:
at least one processor configured for:
obtaining a first model for predicting a current energy of an electromechanical equipment and a measurement frequency of said energy;
predicting, via said prediction model, the energy of said equipment, using, as input for said model, a result of a first measurement of said current energy of said equipment and data representing a context of said equipment during and/or since the first measurement, said prediction being carried out before and/or during a second measurement subsequent to said first measurement and carried out while complying with said obtained measurement frequency with respect to said first measurement;
varying the measurement frequency of at least one measurement of the energy of said equipment, subsequent to said second measurement, as a function of a difference between said predicted energy and said second measurement.

17. The electronic device of claim 16, said at least one processor being configured for obtaining at least one indication relating to at least one type of contextual data to be used for said prediction model, and wherein said obtaining of contextual data takes into account said obtained indication.

18. The electronic device of claim 16, wherein obtaining said prediction model and said measurement frequency comprises:
building a plurality of prediction models from an initial prediction model, said plurality of prediction models being obtained by a plurality of training phases of said initial prediction model taking into account a history of measurement results of the current energy of said equipment associated with data representing a context of said equipment between said and/or during said measurements, said measurements being carried out with different measurement frequencies in said plurality of training phases;
and wherein said obtained model is selected from said built models taking into account said measurement frequencies and/or steps and accuracies of said built models, said obtained measurement frequency being the measurement frequency used for training said selected prediction model.

19. A non transitory recording medium that can be read by a processor of an electronic device and on which a computer program is recorded that comprises instructions for implementing, when the program is executed by the processor, the method of claim 1.

20. A non transitory recording medium that can be read by a processor of an electronic device and on which a computer program is recorded that comprises instructions for implementing, when the program is executed by the processor, the method of claim 8.
